(19) United States
(12) Patent Application Publication
(10) Pub. No.: US 2026/0075989 A1
(43) Pub. Date: Mar. 12, 2026

(54) LIGHT EMITTING DIODE AND MANUFACTURING METHOD THEREOF

(71) Applicant: Taiwan-Asia Semiconductor Corporation, Hsinchu City (TW)

(72) Inventors: Ching-Yuan Tsai, Hsinchu City (TW); Hong-Ta Cheng, Hsinchu City (TW); Yao-Hong Huang, Hsinchu City (TW)

(21) Appl. No.: 19/093,619

(22) Filed: Mar. 28, 2025

(30) Foreign Application Priority Data
Sep. 10, 2024 (TW) 113134274

(51) Int. Cl. H10H 20/824; H10H 20/01; H10H 20/814; H10H 20/82

(52) U.S. Cl. CPC H10H 20/8242; H10H 20/0133; H10H 20/814; H10H 20/82

(57) ABSTRACT

A light-emitting diode and a manufacturing method thereof are provided. The light-emitting diode includes a substrate, a reflective mirror layer, an epitaxial composite layer and a plurality of conductive plugs. The reflective mirror layer is disposed on the substrate, and the epitaxial composite layer has a light-emitting layer and a quaternary compound semiconductor layer. The quaternary compound semiconductor layer directly contacts and electrically connects the reflective mirror layer. There is no dielectric material arranged between the quaternary compound semiconductor layer and the reflective mirror layer. The plurality of conductive plugs are alloyed and diffused within the quaternary compound semiconductor layer and do not protrude above the upper surface of the quaternary compound semiconductor layer, and form ohmic contact with the reflective mirror layer.

### CROSS-REFERENCES TO RELATED APPLICATIONS

This application claims the benefit of priority to Taiwanese Patent Application No. 113134274 filed on Sep. 10, 2024, which is hereby incorporated by reference in its entirety.

### BACKGROUND OF THE INVENTION

### Field of the Invention

The present invention relates to a light-emitting diode and a manufacturing method thereof, in particular to a light-emitting diode with high brightness and a manufacturing method thereof.

### Descriptions of the Related Art

Light-emitting diodes (LEDs) have the advantages of high brightness, small size, low power consumption and long life, and is widely used in lighting or display products. In pursuit of the goals of developing different sizes and improving brightness of short-wavelength infrared (SWIR) light-emitting diodes, conventional technologies usually focus on the P-type ohmic contact metal and mirror reflection in the light-emitting diode structure. The system will perform different structural tests to improve light reflection and extraction efficiency. Specifically, please refer to FIG. 1, which shows a light-emitting diode 1 in the currently common infrared band. This type of light-emitting diode 1 has an epitaxial composite layer 10, a dielectric layer 20 in its structure and a plurality of conductive plugs 30 arranged around the dielectric layer 20. A transparent conductive layer 40 and a reflective mirror layer 50 are provided below the conductive plugs 30. The light emitted by the light-emitting layer in the epitaxial composite layer 10 can pass through the dielectric layer 20 and the transparent conductive layer 40 and then be reflected upward by the mirror layer 50 and then emitted outward for thereby improving the light extraction efficiency (LEE) of the light-emitting diode and increase brightness.

However, when the light reflected by the mirror layer 50 passes through the dielectric layer 20, part of the light will be absorbed and scattered so the brightness will be reduced accordingly. In order to overcome the above problems, the industry is in urgent need of a light-emitting diode structure and an innovative manufacturing method of increasing brightness while reducing cost.

### SUMMARY OF THE INVENTION

The main objective of the present invention is to provide a light-emitting diode with high brightness, simplified process steps and low cost by alloying and diffusing the conductive plugs which originally act as ohmic metal contacts within the epitaxial composite layer and then planarizing the surface thereof. An evaporation process is performed thereafter to form a reflective mirror system. This innovative structure can reduce the problems of light being absorbed or scattered by the dielectric layer and transparent conductive layer in the original structure during reflection, and thereby, to achieve the effect of improving brightness. In addition, the reflection effect of the reflective mirror system is better in the flat structure of the point-shaped conductive plugs. In addition to improving brightness, this innovative structure can also reduce the cost of depositing dielectric layers and transparent conductive layers existed in traditional structures.

To achieve the above objective, the present invention discloses a light-emitting diode which includes a substrate, a reflective mirror layer, an epitaxial composite layer and a plurality of conductive plugs. The reflective mirror layer is disposed on the substrate, and the epitaxial composite layer has a quaternary compound semiconductor layer. The quaternary compound semiconductor layer directly contacts and electrically connects the reflective mirror layer. There is no dielectric material arranged between the quaternary compound semiconductor layer and the reflective mirror layer. The plurality of conductive plugs are alloyed and diffused within the quaternary compound semiconductor layer, do not protrude above the upper surface of the quaternary compound semiconductor layer, and form ohmic contact with the reflective mirror layer.

In one embodiment of a light-emitting diode of the present invention, the quaternary compound semiconductor layer is a Zn-doped InGaAsP layer.

In one embodiment of a light-emitting diode of the present invention, a thickness of the quaternary compound semiconductor layer is 300˜1000 angstroms (Å).

In one embodiment of a light-emitting diode of the present invention, each of the conductive plugs is a metal stacked layer, and the metal stacked layer is one of a titanium (Ti)/platinum (Pt)/gold (Au) stack or a titanium (Ti)/gold (Au) stack.

In one embodiment of a light-emitting diode of the present invention, a depth of each of the conductive plugs alloyed and diffused within the quaternary compound semiconductor layer is 20˜200 angstroms (Å).

In one embodiment of a light-emitting diode of the present invention, the material of the reflective mirror layer is selected from one of the group consisting of silver (Ag), titanium (Ti), platinum (Pt), gold (Au) and their combinations.

In one embodiment of a light-emitting diode of the present invention, the epitaxial composite layer further comprises a light-emitting layer, a first compound semiconductor layer and a second compound semiconductor layer, the first compound semiconductor layer and the second compound semiconductor layer sandwich the light-emitting layer, and the second compound semiconductor layer is disposed between the light-emitting layer and the quaternary compound semiconductor layer.

In one embodiment of a light-emitting diode of the present invention, the first compound semiconductor layer is an InP layer and the second compound semiconductor layer is a Zn-doped InP layer.

In one embodiment of a light-emitting diode of the present invention, a wavelength of the light-emitting layer is 1100˜1700 nanometers (nm).

In one embodiment of a light-emitting diode of the present invention, the light-emitting diode further comprises an upper electrode disposed on the epitaxial composite layer and does not vertically overlap with conductive plugs.

To achieve the above objective, the present invention discloses a manufacturing method of a light-emitting diode comprising the following steps: providing an epitaxial composite layer having a quaternary compound semiconductor layer, providing a plurality of conductive plugs formed on the quaternary compound semiconductor layer, alloying and diffusing the conductive plugs within the quaternary compound semiconductor layer and not protruding above the upper surface of the quaternary compound semiconductor layer, and providing a reflective mirror layer formed on the quaternary compound semiconductor layer electrically connecting the quaternary compound semiconductor layer and forming ohmic contact with the conductive plugs and having no dielectric material arranged between the quaternary compound semiconductor layer and the reflective mirror layer.

In one embodiment of a method of manufacturing a light-emitting diode of the present invention, the quaternary compound semiconductor layer is a Zn-doped InGaAsP layer.

In one embodiment of a method of manufacturing a light-emitting diode of the present invention, the step of providing the conductive plugs is to provide and pattern a metal stacked layer which is one of a titanium (Ti)/platinum (Pt)/gold (Au) stack or a titanium (Ti)/gold (Au) stack.

In one embodiment of a method of manufacturing a light-emitting diode of the present invention, the step of alloying and diffusing the conductive plugs within the quaternary compound semiconductor layer is to diffuse the conductive plugs to a depth of 20˜200 angstroms (Å) within the quaternary compound semiconductor layer.

In one embodiment of a method of manufacturing a light-emitting diode of the present invention, after the step of alloying and diffusing the conductive plugs within the quaternary compound semiconductor layer further comprises a step of removing the parts of the conductive plugs protruding the upper surface of the quaternary compound semiconductor layer by wet etching.

In one embodiment of a method of manufacturing a light-emitting diode of the present invention, the step of providing a reflective mirror layer is to provide a reflective mirror layer made by a material selected from one of a group consisting of silver (Ag), titanium (Ti), platinum (Pt), gold (Au) and their combinations.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic diagram of a conventional light-emitting diode;

FIG. 2(A) to 2(H) are schematic diagrams illustrating the manufacturing process of a light-emitting diode in an embodiment of the present invention;

FIG. 3 is a top-view schematic diagram of a light-emitting diode in an embodiment of the present invention; and

FIG. 4 is a schematic diagram illustrating the process steps of the light-emitting diode of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

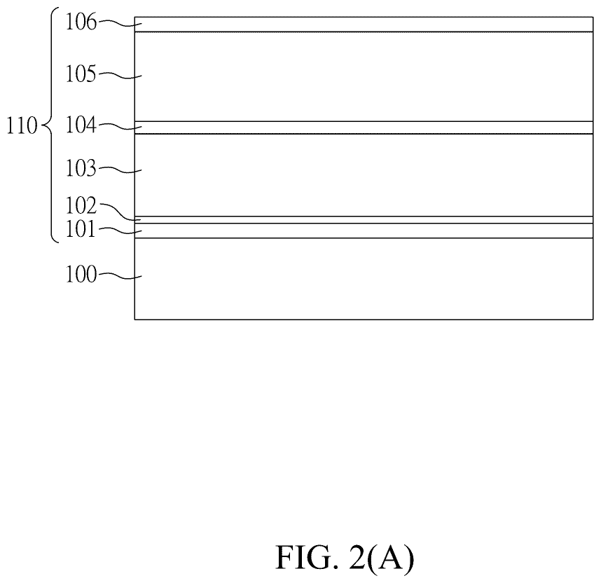

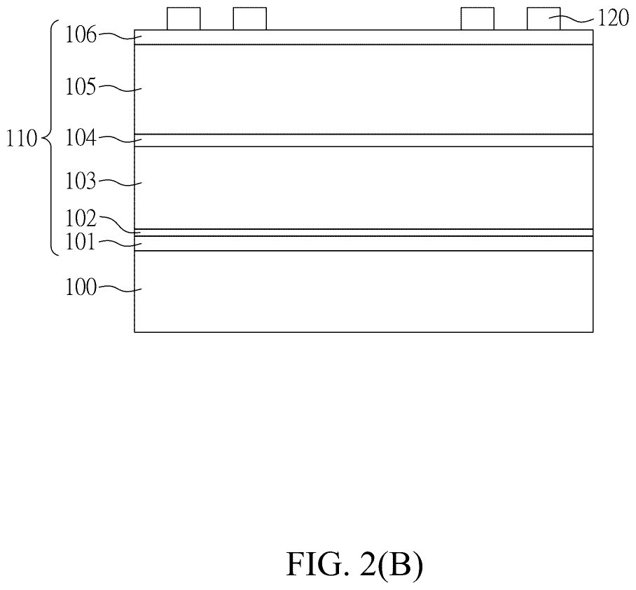

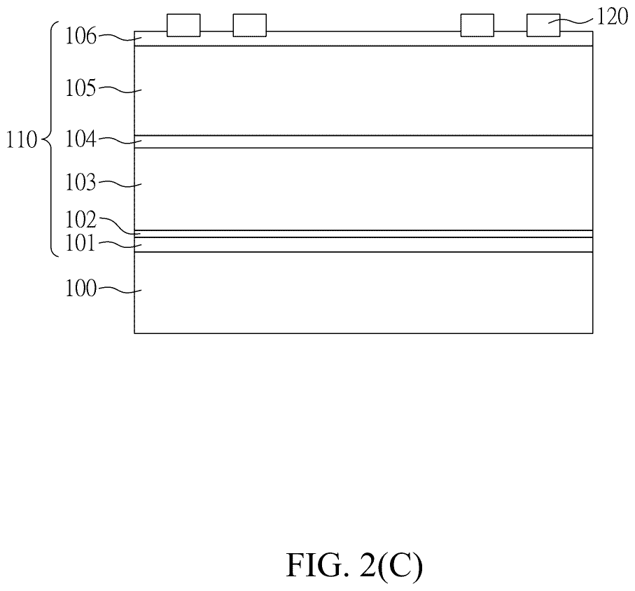

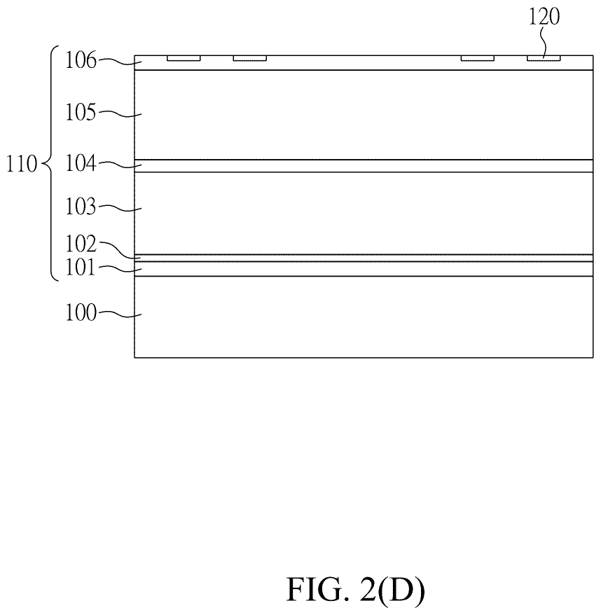

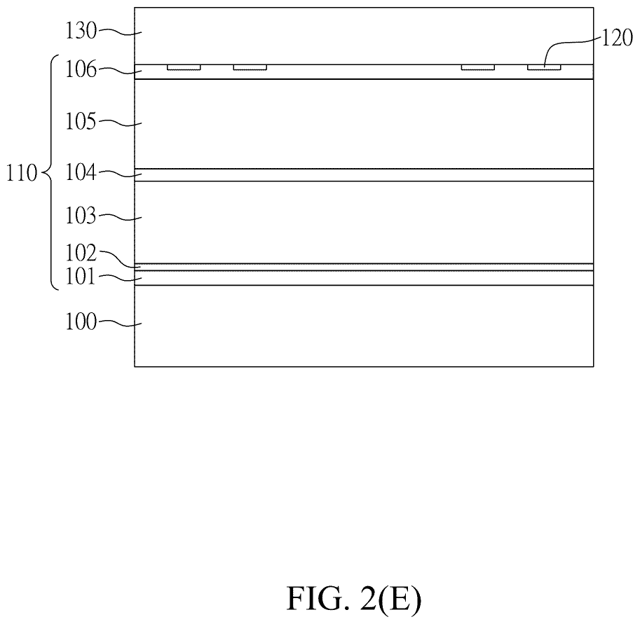

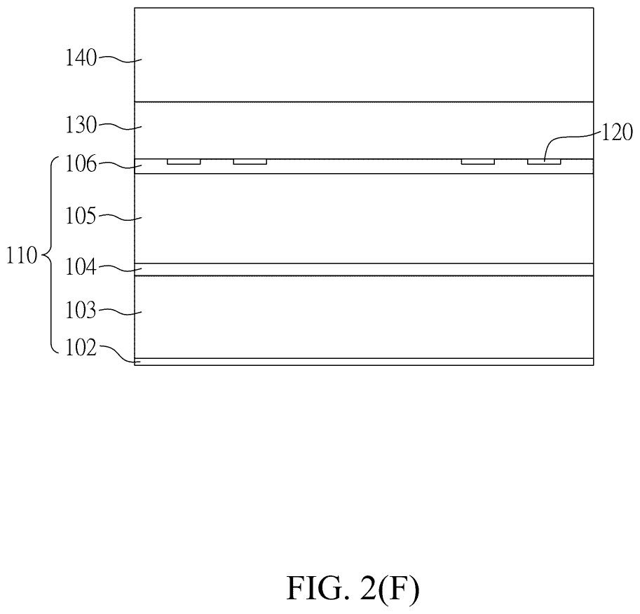

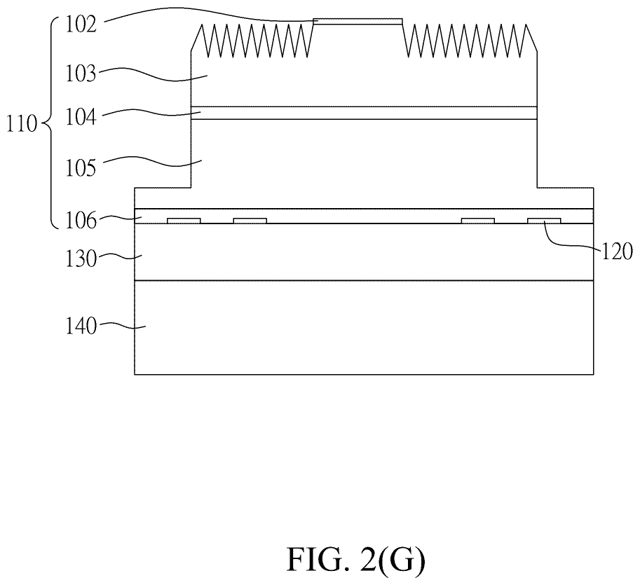

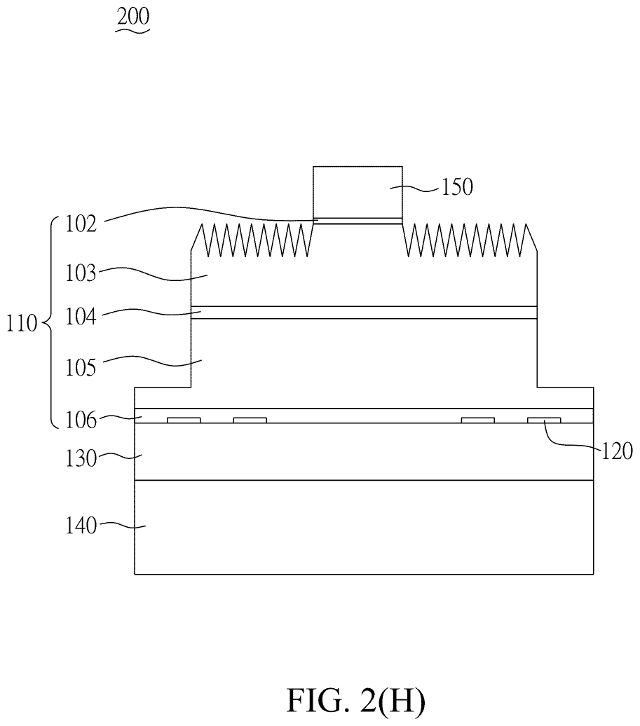

The present invention discloses a light-emitting diode and a manufacturing method thereof. Specifically, the light-emitting diode disclosed in the present invention includes flattened point-shaped conductive plugs which can improve the reflection efficiency of the mirror system and the light extraction efficiency, while reducing the scattering issues caused by the transparent conductive layer and dielectric layer in conventional structures, as described in detail below. Referring to FIG. 2(A), an epitaxial composite layer 110 is grown on a silicon substrate 100 using metal organic chemical vapor deposition (MOCVD) or molecular beam epitaxy (MBE) techniques. The epitaxial composite layer 110 comprises a first compound semiconductor layer 103, a light-emitting layer 104, and a second compound semiconductor layer 105. The light-emitting layer 104 is a multiple quantum well (MQW) structure sandwiched between the first compound semiconductor layer 103 and the second compound semiconductor layer 105. In this embodiment, the light-emitting wavelength of the multiple quantum wells is in the range of 1100 to 1700 nanometers (nm).

Specifically, the first compound semiconductor layer 103 is an N-type indium phosphide (InP) epitaxial layer, and the second compound semiconductor layer 105 is a P-type zinc-doped indium phosphide (Zn-doped InP) epitaxial layer. It should be noted that the materials described in this embodiment are just examples, and the invention is not limited thereto. In actual applications, the materials and compositions can be adjusted according to the emission wavelength. For instance, the epitaxial layers can include materials like aluminum gallium arsenide (AlGaAs), indium gallium arsenide (InGaAs), etc. Specifically, the first compound semiconductor layer 103, located outside the multiple quantum well structure, helps electron injection into the MQW and limits carrier escape for providing optical confinement and restricting the light field's propagation range within the MQW and thereby enhancing the light-emitting efficiency. The P-type zinc-doped indium phosphide layer 105 increases the hole concentration for enabling effective hole injection into the MQW structure and facilitating recombination with electrons. Additionally, the P-type indium phosphide epitaxial layer provides good lateral current spreading for ensuring that the current is uniformly distributed across the entire light-emitting structure when a bias is applied and further enhancing the light-emitting efficiency.

Moreover, in this embodiment, an N-type indium gallium arsenide (InGaAs) epitaxial layer 102 and an N-type indium phosphide (InP) epitaxial layer 101 are configured to be disposed between the first compound semiconductor layer 103 and the silicon substrate 100. The N-type InP layer 101 is used to adjust the lattice matching between the silicon substrate 100 and the epitaxial composite layer 110 during subsequent epitaxial growth for reducing stress caused by lattice mismatch during the growth process and thus improving the quality of the epitaxial layers in the subsequent processes. The N-type InGaAs layer 102 has a lattice constant between that of the InP epitaxial layer and the MQW structure for acting as a buffer layer to further regulate the lattice matching of the epitaxial layers. Moreover, the N-type InGaAs layer 102 can optimize carrier injection efficiency by adjusting its bandgap through the ratio of gallium and indium for thereby controlling electron and hole transport and ensuring more carriers are effectively injected into the light-emitting layer. Thus, the light-emitting efficiency is enhanced.

Furthermore, the epitaxial composite layer 110 further includes a quaternary compound semiconductor layer 106. In this embodiment, the quaternary compound semiconductor layer 106 is a zinc-doped indium gallium arsenide phosphide (Zn-doped InGaAsP) epitaxial layer, with a preferred thickness of 300 to 1000 angstroms (Å). The zinc-doped InGaAsP epitaxial layer has an adjustable bandgap suitable for the emission wavelength of the multiple quantum well structure. It also has low lateral resistance and good lateral current spreading properties for ensuring effective current diffusion laterally.

Referring to FIG. 2(B), a metal stack is deposited on the upper surface of the quaternary compound semiconductor layer 106 using techniques such as evaporation or sputtering. This metal stack can consist of layers such as titanium (Ti)/platinum (Pt)/gold (Au) or titanium (Ti)/gold (Au), or other combinations of metal materials, with a thickness of 2000 to 5000 angstroms (Å). Subsequently, a patterning process is performed on the metal stack to form multiple conductive plugs 120 on the upper surface of the quaternary compound semiconductor layer 106 for ensuring that the vertical current between the upper and lower electrodes of the light-emitting diode chip is uniformly distributed throughout the crystal structure. Next, as shown in FIG. 2(C), a heating alloying process is performed for allowing the conductive plugs 120 to be diffused into the quaternary compound semiconductor layer 106. The depth of diffusion for each conductive plug 120 is approximately 20 to 200 angstroms (Å). Next, as shown in FIG. 2(D), a planarization process is performed using wet etching to remove parts of the conductive plugs 120 protruding from the upper surface of the quaternary compound semiconductor layer 106 for exposing the upper surface of each conductive plug 120 while ensuring that none of the conductive plugs 120 protrude from the surface of the quaternary compound semiconductor layer 106. In other words, the surface of the epitaxial composite layer 110, including the quaternary compound semiconductor layer 106 and the upper surface of each conductive plug 120, collectively forms a flat surface.

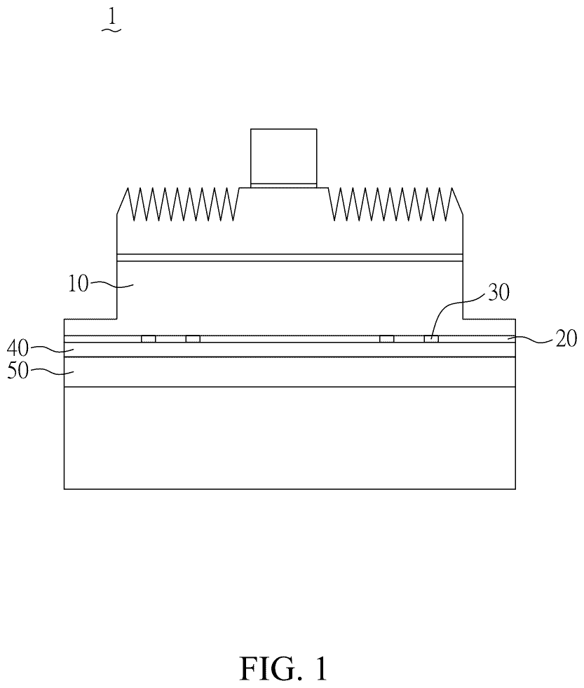

Referring to FIG. 2(E), a reflective layer 130 is deposited on the upper surface of the quaternary compound semiconductor layer 106. This reflective layer is also a metal stack, which can be deposited on the upper surface of the quaternary compound semiconductor layer 106 using methods such as metal evaporation or sputtering. The reflective layer 130 is made from materials selected from one of a group consisting of silver (Ag), titanium (Ti), platinum (Pt), and gold (Au), and combinations thereof. For example, the first stage can involve depositing a silver (Ag)/titanium (Ti) stack on the surface of the quaternary compound semiconductor layer 106, followed by sequential deposition of titanium (Ti)/platinum (Pt)/gold (Au) layers to form the reflective mirror system of the light-emitting diode. This reflective layer has a high reflectivity, which effectively reflects light within the light-emitting diode structure outward for increasing light intensity and reducing light absorption losses within the structure. It should be noted that, in contrast to the traditional structure shown in FIG. 1, the reflective layer 130 of the present invention is directly in contact with and electrically connected to the quaternary compound semiconductor layer 106 for forming an ohmic contact with each conductive plug 120. Moreover, the quaternary compound semiconductor layer 106 and conductive plugs 120 together form a flat surface that enhances the reflection performance of the reflective layer 130 in its smooth structure. Additionally, different from the conventional structures, there is no dielectric material nor transparent conductive layer arranged between the quaternary compound semiconductor layer 106 and the reflective layer 130. As a result, light emitted from the light-emitting layer, after being reflected upwards by the reflective layer 130, can directly exit the epitaxial composite layer 110 without suffering losses due to absorption or scattering from the dielectric material or transparent conductive layer existed in the conventional structure. Thereby, light extraction efficiency and the brightness of the light-emitting diode is significantly improved and enhanced.

Referring to FIG. 2(F), a wafer bonding technique is used to bond the silicon substrate 100 with another permanent substrate 140. This permanent substrate 140 can be, but is not limited to, a silicon substrate or a sapphire substrate. After bonding the reflective layer 130 of the silicon substrate 100 to the permanent substrate 140, a wafer removal process is performed to remove the silicon substrate 100 and its buffer layer (i.e., the N-type indium phosphide epitaxial layer 101) from the opposite side of the permanent substrate 140 for exposing the N-type indium gallium arsenide epitaxial layer 102. Then, the wafer is flipped over, with the permanent substrate 140 acting as the bottom supporting structure for the light-emitting diode chip for facilitating subsequent processes such as wafer dicing. As shown in FIG. 2(G), a patterning process is performed on the N-type indium gallium arsenide epitaxial layer 102 and the first compound semiconductor layer 103 to define the planar regions where the upper electrode will be formed. A mesa etching process is then performed to etch parts of the epitaxial composite layer 110, including the first compound semiconductor layer 103, the light-emitting layer 104, and the second compound semiconductor layer 105 for creating cutting lines between individual light-emitting dies on the permanent substrate 140. Further, the first compound semiconductor layer 103 is roughened, and a protective layer (not shown) is formed on the wafer surface for giving the first compound semiconductor layer 103 an irregular shape to reduce the total internal reflection of emitted light back into the epitaxial structure. Thus, light extraction efficiency is improved. Finally, as shown in FIG. 2(H), the upper electrode 150 is formed on the patterned planar region of the N-type indium gallium arsenide epitaxial layer 102 and the first compound semiconductor layer 103 for forming the final structure of the light-emitting diode 200 in this invention.

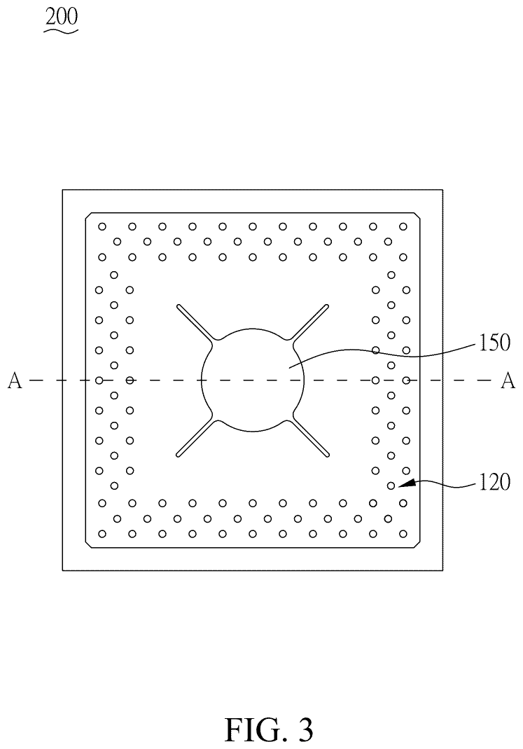

Referring to FIG. 3, a top-down schematic view of the light-emitting diode structure of the present invention is shown, with multiple point-shaped conductive plugs 120 and the upper electrode 150 arranged so that they do not overlap vertically. The configuration of the upper electrode 150 and the point-shaped conductive plugs 120 in the vertical distribution achieves vertical current spreading. Additionally, light emitted from the light-emitting layer is prevented from being blocked by the upper electrode 150 for further enhancing light extraction efficiency. In a preferred embodiment of the invention, the total area occupied by the multiple point-shaped conductive plugs 120 in the light-emitting diode is approximately 2.2% to 3.2% of the area of the epitaxial composite layer after the mesa process.

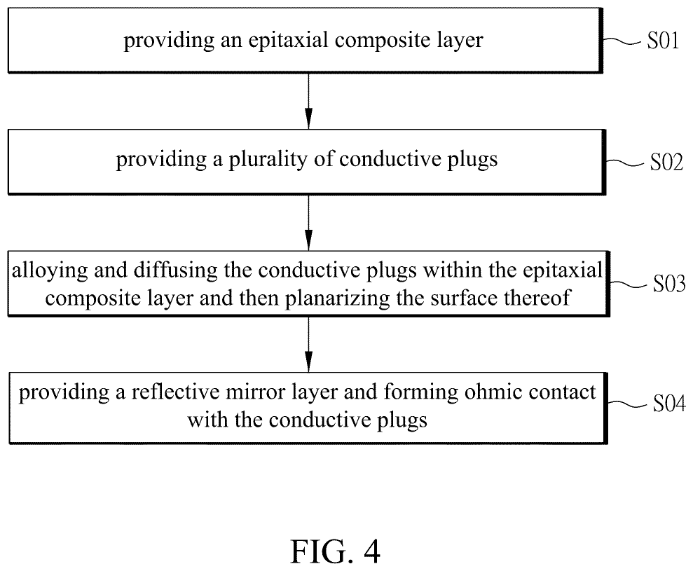

Referring to FIG. 4, the process flow diagram for manufacturing the light-emitting diode of the present invention is shown. In step S01, an epitaxial composite layer is provided, including a light-emitting layer and a quaternary compound semiconductor layer. In step S02, multiple conductive plugs are formed on the quaternary compound semiconductor layer. In step S03, alloy diffusion is performed on the conductive plugs in the quaternary compound semiconductor layer. In step S04, a reflective layer is provided, directly formed on the quaternary compound semiconductor layer, electrically connected to the quaternary compound semiconductor layer and forming an ohmic contact with the conductive plugs. Further details of the related components in the process can be referred to in the previous description and are not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A light-emitting diode, comprising:
a substrate;
a reflective mirror layer, disposed on the substrate;
an epitaxial composite layer, having a quaternary compound semiconductor layer directly contacting and electrically connecting the reflective mirror layer and having no dielectric material arranged between the quaternary compound semiconductor layer and the reflective mirror layer; and
a plurality of conductive plugs, alloyed and diffused within the quaternary compound semiconductor layer and not protruding above the upper surface of the quaternary compound semiconductor layer, and forming ohmic contact with the reflective mirror layer.

2. The light-emitting diode of claim 1, wherein the quaternary compound semiconductor layer is a Zn-doped InGaAsP layer.

3. The light-emitting diode of claim 1, wherein a thickness of the quaternary compound semiconductor layer is 300˜1000 angstroms (Å).

4. The light-emitting diode of claim 1, wherein each of the conductive plugs is a metal stacked layer, and the metal stacked layer is one of a titanium (Ti)/platinum (Pt)/gold (Au) stack or a titanium (Ti)/gold (Au) stack.

5. The light-emitting diode of claim 1, wherein a depth of each of the conductive plugs alloyed and diffused within the quaternary compound semiconductor layer is 20˜200 angstroms (Å).

6. The light-emitting diode of claim 1, wherein the material of the reflective mirror layer is selected from one of the group consisting of silver (Ag), titanium (Ti), platinum (Pt), gold (Au) and their combinations.

7. The light-emitting diode of claim 1, wherein the epitaxial composite layer further comprises a light-emitting layer, a first compound semiconductor layer and a second compound semiconductor layer, the first compound semiconductor layer and the second compound semiconductor layer sandwich the light-emitting layer, and the second compound semiconductor layer is disposed between the light-emitting layer and the quaternary compound semiconductor layer.

8. The light-emitting diode of claim 7, wherein the first compound semiconductor layer is an InP layer and the second compound semiconductor layer is a Zn-doped InP layer.

9. The light-emitting diode of claim 7, wherein a wavelength of the light-emitting layer is 1100˜1700 nanometers (nm).

10. The light-emitting diode of claim 1, further comprising an upper electrode disposed on the epitaxial composite layer and does not vertically overlap with conductive plugs.

11. A manufacturing method of a light-emitting diode, comprising:
providing an epitaxial composite layer, having a quaternary compound semiconductor layer;
providing a plurality of conductive plugs, formed on the quaternary compound semiconductor layer;
alloying and diffusing the conductive plugs within the quaternary compound semiconductor layer and not protruding above the upper surface of the quaternary compound semiconductor layer; and
providing a reflective mirror layer, formed on the quaternary compound semiconductor layer, electrically connecting the quaternary compound semiconductor layer and forming ohmic contact with the conductive plugs and having no dielectric material arranged between the quaternary compound semiconductor layer and the reflective mirror layer.

12. The manufacturing method of a light-emitting diode of claim 11, wherein the quaternary compound semiconductor layer is a Zn-doped InGaAsP layer.

13. The manufacturing method of a light-emitting diode of claim 11, wherein the step of providing the conductive plugs is to provide and pattern a metal stacked layer, and the metal stacked layer is one of a titanium (Ti)/platinum (Pt)/gold (Au) stack or a titanium (Ti)/gold (Au) stack.

14. The manufacturing method of a light-emitting diode of claim 11, wherein the step of alloying and diffusing the conductive plugs within the quaternary compound semiconductor layer is to diffuse the conductive plugs to a depth of 20˜200 angstroms (Å) within the quaternary compound semiconductor layer.

15. The manufacturing method of a light-emitting diode of claim 11, wherein after the step of alloying and diffusing the conductive plugs within the quaternary compound semiconductor layer further comprises a step of removing the parts of the conductive plugs protruding the upper surface of the quaternary compound semiconductor layer by wet etching.

16. The manufacturing method of a light-emitting diode of claim 11, wherein the step of providing a reflective mirror layer is to provide a reflective mirror layer made by a material selected from one of a group consisting of silver (Ag), titanium (Ti), platinum (Pt), gold (Au) and their combinations.
